(19) United States
(12) Patent Application Publication
(10) Pub. No.: US 2015/0115346 A1
(43) Pub. Date: Apr. 30, 2015

(54) SEMICONDUCTOR MEMORY DEVICE AND METHOD FOR MANUFACTURING THE SAME

(71) Applicant: UNITED MICROELECTRONICS CORP., Hsin-Chu City (TW)

(72) Inventors: Cheng-Yuan Hsu, Hsinchu City (TW); ZHIGUO LI, Singapore (SG); CHI REN, Singapore (SG)

(73) Assignee: UNITED MICROELECTRONICS CORP., Hsin-Chu City (TW)

(21) Appl. No.: 14/062,905

(22) Filed: Oct. 25, 2013

(51) Int. Cl. H01L 27/115; H01L 29/423; H01L 29/66; H01L 29/06

(52) U.S. Cl. CPC H01L 27/11521; H01L 29/0649; H01L 29/42324; H01L 29/66825
USPC 257/317; 438/257

(57) ABSTRACT

A semiconductor memory device includes a substrate, shallow trench isolations protruding from the substrate, a floating gate formed conformally on the surface of the recess between each shallow trench isolation, a tunnel layer formed between each floating gate and the substrate, a dielectric layer formed conformally on the floating gates, and a control gate formed on the dielectric layer.

### BACKGROUND OF THE INVENTION

1. Field of the Invention

The present invention relates to a semiconductor memory device, and more particularly, to a semiconductor memory device with higher gate coupling ratio and method for manufacturing the same.

2. Description of the Prior Art

Non-volatile memories (NVMs) are used in a wide variety of commercial and military electronic devices and equipment, such as hand-held telephones, radios and digital cameras. The market for these electronic devices continues to demand devices with a lower voltage, lower power consumption and a decreased chip size. Some examples of NVMs include an EPROM, an EEPROM and a flash memory cell.

Generally, flash memories or flash memory cells comprise a MOSFET with a plurality of floating gates (FG) between a control gate (CG) and a channel region, the FG(s) and the CG being separated by a thin dielectric layer. With the improvement of fabrication technologies, the FG size and the space between FGs has been reduced to sub-micrometer scale. These devices are basically miniature EEPROM cells in which electrons (or holes) are injected or tunneled through an oxide barrier in a FG. Charges stored in the FG modify the device threshold voltage. In this way, data is stored. The CG controls the FG. The FG to CG coupling ratio, which usually referred as gate coupling ration (GCR), is related to the area overlap between the FG and the CG, and should be as great as possible. It affects the read/write speed of the flash memory. Furthermore, the better the coupling ratio, the more the required operation voltage of the memory cell can be reduced. However, it is a disadvantage of known FG memory devices that they have a small gate coupling ratio between the FG and the CG.

Moreover, as will be appreciated by one skilled in the art, the etch-back process is usually used in conventional methods to remove the insulating material and form the floating gate structure. The etch-back process is sensitive to the pattern density. This means the micro-loading effect may influence the thickness uniformity of the final floating gate structure, thereby impacting the cell performance. Also, the process of using the etch-back process on thick floating gate deposition to form a floating gate may have a narrow process window and is not easy to control.

### SUMMARY OF THE INVENTION

It is therefore one objectives of the present invention to provide a semiconductor memory device with larger gate coupling ratio (GCR) and better performance, and a method for manufacturing this semiconductor memory device with larger process window and better controllability.

One object of the present invention is to provide a semiconductor memory device which includes a substrate, a plurality of shallow trench isolations protruding from the substrate, wherein a recess is formed between each shallow trench isolation on the substrate, a floating gate formed conformally on the surface of each recess, a tunnel layer formed between the substrate and each floating gate, a dielectric layer formed conformally on the shallow trench isolations and the floating gates, and a control gate formed on the dielectric layer.

Another object of the present invention is to provide a method for manufacturing a semiconductor memory device, which includes the steps of providing a substrate, forming a plurality of shallow trench isolations protruding from the substrate, wherein a recess is formed between each shallow trench isolation on the substrate, forming a tunnel layer on the substrate between each shallow trench isolation, forming a floating gate layer conformally on the shallow trench isolations and the tunnel layer, and performing a chemical mechanical polishing process to remove a part of the floating gate layer, so that remaining floating gate layer in each recess forms a floating gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIGS. 1-7 are cross-sectional views schematically depicting a process flow for manufacturing a semiconductor memory device in accordance with one embodiment of present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following detailed description of the present invention, reference is made to the accompanying drawings which form a part hereof and is shown by way of illustration and specific embodiments in which the invention may be practiced. These embodiments are described in sufficient details to enable those skilled in the art to practice the invention. Other embodiments may be utilized and structural, logical, and electrical changes may be made without departing from the scope of the present invention. The following detailed description, therefore, is not to be taken in a limiting sense, and the scope of the present invention is defined by the appended claims.

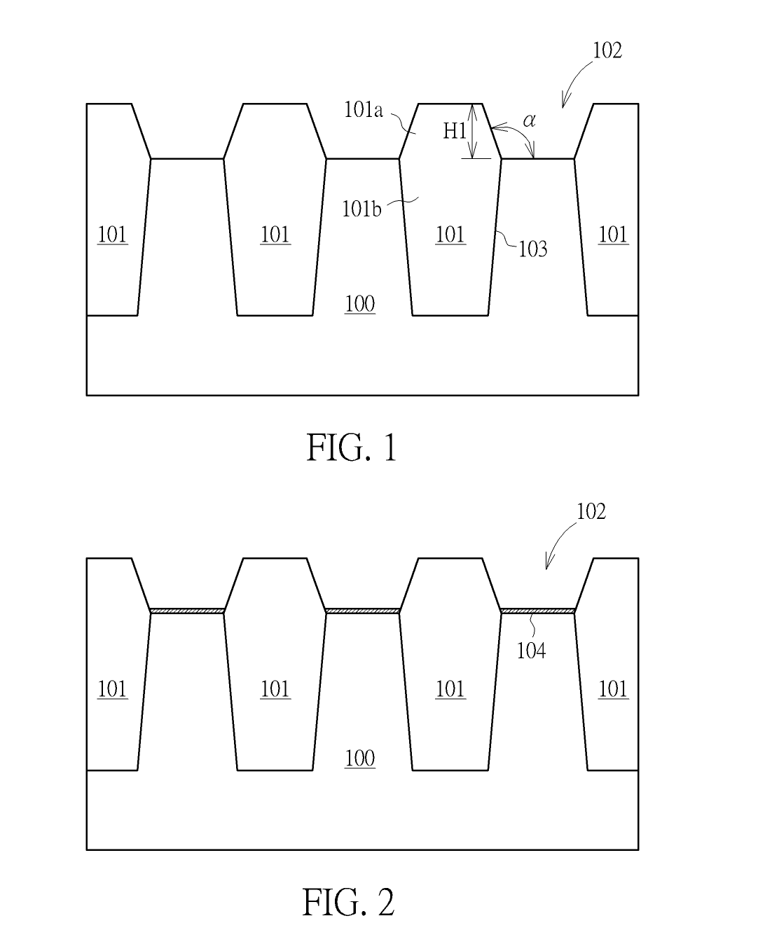

Please refer to FIGS. 1-7, which are cross-sectional views schematically depicting a process flow for manufacturing a semiconductor device in accordance with one embodiment of the present invention. First, as shown in FIG. 1, a semiconductor substrate 100 is provided to serve as a base for forming devices, components, or circuits. The substrate 100 is preferably composed of a silicon containing material. Silicon containing materials include, but are not limited to, Si, single crystal Si, polycrystalline Si, SiGe, single crystal silicon germanium, polycrystalline silicon germanium, or silicon doped with carbon, amorphous Si and combinations and multi-layered materials thereof. The semiconductor substrate 100 may also be composed of other semiconductor materials, such as germanium, and compound semiconductor substrates, such as type III/V semiconductor substrates, e.g., GaAs. Although the semiconductor substrate 100 is depicted as a bulk semiconductor substrate, the arrangement of a semiconductor on an insulator substrate, such as silicon-on-insulator (SOI) substrates, are also suitable for the semiconductor substrate 100.

Refer again to FIG. 1, a plurality of shallow trench isolations (STIs) 101 are formed on the substrate 100. These STIs 101 may be disposed on the substrate 100 in an array fashion, so that the STIs 101 are spaced-apart from each other at regular intervals and define the basic memory cell patterns. The STI 101 includes a portion 101a protruding from the substrate 100 and a portion 101b buried in the substrate 100. A recess 102 is defined between each STI 101 on the substrate 100. These recesses 102 will be used for accommodating the floating gate in later processes. Please note that in the embodiment, the STI 101 is designed with special profile to improve the gate coupling ratio (GCR) of floating gates. For this purpose, as shown in FIG. 1, the protruding portion 101a of the STI 101 is in an upwardly-tapered shape, so that the angle α between the surface of the protruding portion 101a and the substrate 100 is an obtuse angle, preferably larger than 100 degrees, rather than an exact right angle. The above-identified tilted sidewall angle α of the recess 102 may improve the GCR. Relevant details and principles will be explained in the following embodiment.

The upwardly-tapered protruding portion 101a of the STI 101 may be formed by the following steps: First, perform an etching process to form a plurality of trenches 103 in the substrate 100. These trenches 103 may taper slightly to the bottom due to the nature of etching process. Second, fill the trenches 103 with isolating material (e.g. SiO₂) to form STIs 101 completely buried in the substrate 100. This step may include a deposition process and a chemical mechanical polishing (CMP) process for removing the unnecessary isolating material on the substrate 100. Third, perform an isotropic etching process with specific etching selectivity on the substrate 100. In this process, the STIs 101 are subjected to merely a few isotropic etchings to form the tapered upper portion 101a, while the etched substrate 100 is thinned to let the tapered portion 101a protrude therefrom. The step height H1 of the protruding portion 101a of the STI 100 may range from 500 nanometers (nm) to 900 nm.

Please refer now to FIG. 2. A tunnel layer 104 is formed on the substrate 100 (i.e. active area on the bottom of the recess 102) between each STI 101. The tunnel layer 104 may be an oxide layer made of e.g., silicon oxide, or the materials with adequate uniform barrier height for carrier tunneling. In the embodiment, the tunnel layer 104 may be formed by atomic layer deposition (ALD) with a preferred thickness from about 80 nm to 100 nm.

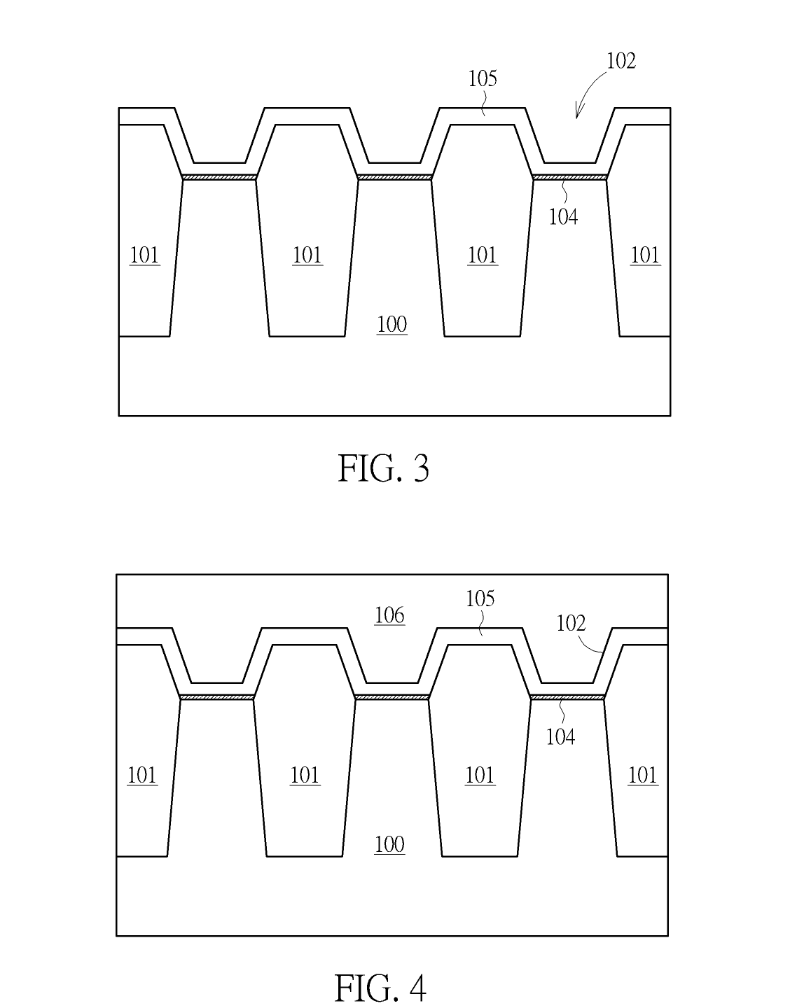

Subsequently, please refer to FIG. 3. A floating gate (FG) layer 105 is conformally formed on the surface of the protruding portions 101a of the STIs 100 and the tunnel layer 104. This FG layer 105 may be formed by chemical vapor deposition (CVD) using poly-silicon with a uniform thickness preferably from 100 nm to 300 nm. Alternatively, the FG layer 105 may be a thin trap layer made of silicon nitride (e.g., used in so-called NROM structure). In the embodiment, the profile of the protruding portions 101a of the STIs 100 is a decisive factor to the surface area of the formed FG layer 105, and the surface area of the FG layer 105 further decides the gate coupling ratio (GCR) of the final floating gate structure. Furthermore, the thickness of the FG layer 105 may also decide the process window of following processes.

Please refer now to FIG. 4. After the FG layer 105 is formed, optionally, a cap layer 106 may be formed on the FG layer 105. The cap layer 106 may be a thick oxide layer (e.g. a thick SiO₂ layer) formed by deposition process for protecting the FG layer 105 from being damaged in following processes. Furthermore, the cap layer 106 fills the recess 102 between the STIs 101 and smoothes the entire topographic profile of the substrate. This may facilitate the performance of the following CMP process. Alternatively, in other embodiments, this process of forming cap layer 106 may also be skipped depending on the process requirements.

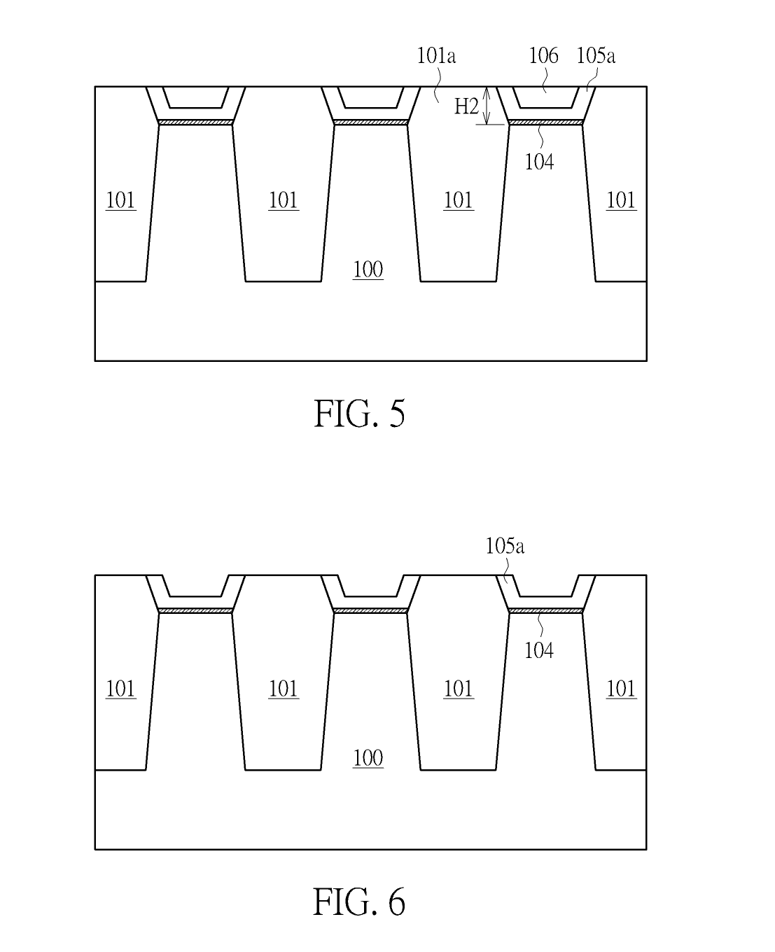

After the cap layer 106 is formed, please refer to FIG. 5, a chemical mechanical polishing (CMP) process is performed to remove a portion of the cap layer 106, the FG layer 105 and the STIs 101. This CMP process removes all the FG layer 105 on the top surfaces of the STIs 101 and reduces the height of the protruding portion 101a of the STI 101 from H1 to H2 (which is preferably about 300 nm to 400 nm), so that the remaining FG layer 105 in each recess 102 becomes a concave U-shaped floating gate 105a with uniform thickness.

After the floating gate 105a is formed, please refer to FIG. 6, the remaining cap layer 106 is removed by an etching process to expose the upper surface of the floating gate 105a. Alternatively, the above removing step may be skipped in the embodiment without the protective cap layer 106.

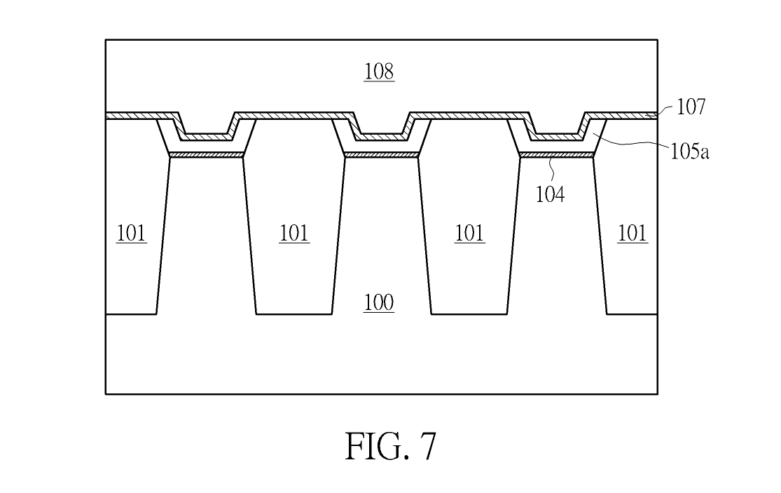

Please now refer to FIG. 7, a dielectric layer 107 is conformally formed on the upper surface of the floating gates 105a and the STIs 101, and a conductive layer 108 is further formed on the conformal dielectric layer 107. The dielectric layer 107 may be made of oxide-nitride-oxide (ONO) multilayer or high-K materials which can electrically isolate the floating gates 105a from the upper control gate 108. The conductive layer 108 may be a poly-Si layer or a metal layer. In later processes, the conductive layer 108 may be further patterned into isolated control gate.

Conventional FG structure made by using etch-back process from a thick FG deposition usually suffers non-uniform thickness, which may quite impact the cell performance. Furthermore, the etch-back process is sensitive to the pattern density. This means the micro-loading effect in array center or edge may further worsen the thickness uniformity of the floating gate structure. One essential feature of the present invention is that the floating gate 105a is made by using the CMP process from a conformal FG layer 105. The conformal FG layer 105 is formed with uniform thickness, so that the final floating gate 105a also has the same uniform thickness after the CMP process.

Moreover, the upwardly-tapered design of protruding STI may efficiently increase the upper surface area of the final floating gate structure. This means the effective gate coupling area may also be increased, thereby improving the gate coupling ratio and cell performance of the memory device. In the present invention, the process factors, such as the tapered angle a between the STIs 101 and the substrate 100, the thickness of the conformal FG layer 105, the step height H1 and H2 before and after the CMP process, may all be properly modified to obtain optimal STI profile and floating gate's shape. The entire process flow may, therefore, be provided with a larger process window and may be easily controlled.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor memory device, comprising:
a substrate;
a plurality of shallow trench isolations protruding from said substrate, wherein a recess is formed between each said shallow trench isolation on said substrate;
a floating gate formed conformally on the surface of each said recess;
a tunnel layer formed between each said floating gate and said substrate;
a dielectric layer formed conformally on said shallow trench isolations and said floating gates; and
a control gate formed on said dielectric layer.

2. A semiconductor memory device according to claim 1, wherein said floating gate is an U-shaped floating gate with uniform thickness.

3. A semiconductor memory device according to claim 1, wherein the thickness of said U-shaped floating gate ranges from 100 nm to 300 nm.

4. A semiconductor memory device according to claim 1, wherein the height of said U-shaped floating gate ranges from 300 nm to 400 nm.

5. A semiconductor memory device according to claim 1, wherein said dielectric layer is an oxide-nitride-oxide multilayer.

6. A semiconductor memory device according to claim 1, wherein the angle between said substrate and said protruding shallow trench isolation is larger than 100 degrees.

7. A semiconductor memory device according to claim 1, wherein said tunnel layer is an oxide layer.

8. A semiconductor memory device according to claim 1, wherein the thickness of said tunnel layer ranges from 80 nm to 100 nm.

9. A method for manufacturing a semiconductor memory device, comprising the steps of:
providing a substrate;
forming a plurality of shallow trench isolations protruding from said substrate, wherein a recess is formed between each said shallow trench isolation on said substrate;
forming a tunnel layer on said substrate between each of said shallow trench isolations;
forming a floating gate layer conformally on said shallow trench isolations and said tunnel layer; and
performing a chemical mechanical polishing process to remove a part of said floating gate layer, so that remaining said floating gate layer in each said recess forms a floating gate.

10. A method for manufacturing a semiconductor memory device according to claim 9, further comprising forming a cap layer on said floating gate layer before performing said chemical mechanical polishing process.

11. A method for manufacturing a semiconductor memory device according to claim 10, wherein said cap layer is an oxide layer.

12. A method for manufacturing a semiconductor memory device according to claim 10, further comprising removing remaining said cap layer after performing said chemical mechanical polishing process.

13. A method for manufacturing a semiconductor memory device according to claim 9, further comprising forming a dielectric layer conformally on said floating gate layer.

14. A method for manufacturing a semiconductor memory device according to claim 13, further comprising forming a control gate on said dielectric layer.
